(19) United States
(12) Patent Application Publication
(10) Pub. No.: US 2025/0309093 A1
(43) Pub. Date: Oct. 2, 2025

(54) POWER RAIL IN STACKED FET DEVICES

(71) Applicant: INTERNATIONAL BUSINESS MACHINES CORPORATION, ARMONK, NY (US)

(72) Inventors: Chen Zhang, Santa Clara, CA (US); Shirin Akter, Irvine, CA (US); Ruilong Xie, Niskayuna, NY (US); Huimei Zhou, Albany, NY (US)

(21) Appl. No.: 18/621,018

(22) Filed: Mar. 28, 2024

(51) Int. Cl. H01L 23/50; H01L 25/10; H10B 10/00

(52) U.S. Cl. CPC H01L 23/50; H01L 25/105; H10B 10/12

(57) ABSTRACT

A semiconductor device includes a memory array including a first ground rail on a backside of the memory array, a first voltage drain to drain (VDD) rail on a frontside of the memory array, and a logic array including a second ground rail on a backside of the logic array. There is a second VDD rail on the backside of the logic array.

### BACKGROUND

### Technical Field

The present disclosure generally relates to transistors, and more particularly, to stacked transistors with power rails on backside and frontside, and methods of creation thereof.

### Description of the Related Art

In the pursuit of maximizing the benefits of stacked FET architecture, novel solutions are explored to further optimize performance, power efficiency, and scalability. One avenue of exploration involves the integration of heterogeneous materials and devices within the stacked structure. By combining different semiconductor materials with complementary properties, such as high electron mobility and low power consumption, designers can create hybrid field-effect transistors (FET) architectures that offer superior performance characteristics. For example, incorporating materials like gallium nitride (GaN) or indium gallium arsenide (InGaAs) in specific layers can enhance carrier mobility and enable faster switching speeds.

### SUMMARY

According to an embodiment, a semiconductor device includes a memory array including a first ground rail on a backside of the memory array, and a first voltage drain to drain (VDD) rail on a frontside of the memory array, and a logic array including a second ground rail on a backside of the logic array, and a second VDD rail on the backside of the logic array.

In one embodiments, which can be combined with the previous embodiment, the memory array further includes a first top transistor stacked over a first bottom transistor. The first top transistor includes a first top source/drain region, and a first contact connecting the first top source/drain region to the first VDD rail through a first top via. The first bottom transistor includes a first bottom source/drain region, and a second bottom source/drain region.

In one embodiments, which can be combined with one or more previous embodiments, the memory array further includes a first backside contact connecting the first bottom source/drain region to the first ground rail, and a second contact connecting the second bottom source/drain region to a bitline through a second top via.

In one embodiments, which can be combined with one or more previous embodiments, at least one of the first top transistor and the first bottom transistor is a field-effect transistor (FET).

In one embodiments, which can be combined with one or more previous embodiments, the memory array is a Static Random Access Memory (SRAM) device.

In one embodiments, which can be combined with one or more previous embodiments, the logic array further includes a second top transistor stacked over a second bottom transistor. The second top transistor includes a second top source/drain region, and a second top contact connecting the second top source/drain region to the second VDD rail through a deep via. The second bottom transistor includes a third bottom source/drain region.

In one embodiments, which can be combined with one or more previous embodiments, the second bottom transistor further incudes a second backside contact connecting the third bottom source/drain region to the second ground rail.

In one embodiments, which can be combined with one or more previous embodiments, at least one of the second top transistor and the second bottom transistor is a field-effect transistor (FET).

According to an embodiment, a method for fabricating a semiconductor device includes forming a memory array including forming a first ground rail on a backside of the memory array, and forming a first voltage drain to drain (VDD) rail on a frontside of the memory array, and forming a logic array. Forming the logic array includes forming a second ground rail on a backside of the logic array, and forming a second VDD rail on a frontside of the logic array.

In one embodiments, which can be combined with the previous embodiment, forming the memory array further includes forming a first top transistor, forming a first bottom transistor and stacking the first top transistor over the first bottom transistor. Forming the first top transistor can include forming a first top source/drain region, and connecting, by a first top contact, the first top source/drain region to the first VDD rail through a first top via. Forming the first bottom transistor includes forming a first bottom source/drain region, and forming a second bottom source/drain region.

In one embodiments, which can be combined with one or more previous embodiments, forming the memory array further includes forming a first backside contact connecting the first bottom source/drain region to the first ground rail, and forming a second contact connecting the second bottom source/drain region to a bitline through a second top via.

In one embodiments, which can be combined with one or more previous embodiments, forming the logic array further includes forming a second top transistor, forming a second bottom transistor, and stacking the second top transistor over the second bottom transistor. Forming the second top transistor includes forming a second top source/drain region, and forming a second top contact connecting the second top source/drain region to the second VDD rail through a second top via. Forming the second bottom transistor includes a third bottom source/drain region.

In one embodiments, which can be combined with one or more previous embodiments, forming the second bottom transistor includes forming a second backside contact connecting the third bottom source/drain region to the second ground rail.

According to an embodiment, a semiconductor device includes a memory array including a first top source/drain region, and a first contact connecting the first top source/drain region to a memory voltage drain to drain (VDD) rail through a first top via. The memory VDD rail is located on a frontside of the memory array, and a logic array including a logic ground rail and a logic VDD rail. The logic ground rail and the logic VDD rail are located on a backside of the logic array.

In one embodiments, which can be combined with the previous embodiment, the memory array further includes a memory ground rail on a backside of the memory array.

In some embodiments, which can be combined with one or more previous embodiments, the memory array further includes a first top transistor stacked over a first bottom transistor. The first bottom transistor includes a first bottom source/drain region, and a second bottom source/drain region.

In one embodiments, which can be combined with one or more previous embodiments, the memory array further includes a first backside contact connecting the first bottom source/drain region to the memory ground rail, and a second contact connecting the second bottom source/drain region to a bitline through a second top via.

In one embodiments, which can be combined with one or more previous embodiments, at least one of the first top transistor and the first bottom transistor is a field-effect transistor (FET).

In one embodiments, which can be combined with one or more previous embodiments, the memory array is a Static Random Access Memory (SRAM) device.

In one embodiments, which can be combined with one or more previous embodiments, the logic array includes a second top transistor stacked over a second bottom transistor. The second top transistor includes a second top source/drain region, and a second top contact connecting the second top source/drain region to the logic VDD rail through a deep top via. The second bottom transistor includes a third bottom source/drain region.

In one embodiments, which can be combined with one or more previous embodiments, the second bottom transistor includes a second backside contact connecting the third bottom source/drain region to the second ground rail.

According to an embodiment, a method of fabricating a semiconductor includes forming a memory array including forming a first top source/drain region, and forming a first contact connecting the first top source/drain region to a memory voltage drain to drain (VDD) rail through a first top via. The memory VDD rail is located on a frontside of the memory array. Forming a logic array includes forming a logic ground rail, and forming a logic VDD rail. The logic ground rail and the logic VDD rail are located on a backside of the logic array.

In one embodiments, which can be combined with the previous embodiment, the method includes forming a first top transistor, and forming a top bottom transistor and stacking the first top transistor over the first bottom transistor. Forming the first bottom transistor includes forming a first bottom source/drain region, and forming a second bottom source/drain region.

In one embodiments, which can be combined with one or more previous embodiments, forming the memory array includes forming a first backside contact connecting the first bottom source/drain region to the memory ground rail, and forming a second contact connecting the second bottom source/drain region to a bitline through a second top via.

In one embodiments, which can be combined with one or more previous embodiments, forming the logic array includes forming a second top transistor, forming a second bottom transistor and stacking the second top transistor over the second bottom transistor. Forming the second top transistor includes forming a second top source/drain region, and forming a second top contact connecting the second top source/drain region to the logic VDD rail through a deep via. Forming the second bottom transistor includes forming a third bottom source/drain region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a semiconductor device, in accordance with some embodiments.

FIG. 1B illustrates a simplified cross-section view of a logic array of a semiconductor device, consistent with an illustrative embodiment.

FIG. 1C illustrates a simplified cross-section view of a memory array of a semiconductor device, consistent with an illustrative embodiment.

FIG. 2 illustrates a top-view of a semiconductor device, in accordance with some embodiments.

FIG. 3 illustrate a block diagram of a method for forming a semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

According to an embodiment, a semiconductor device includes a memory array including a first ground rail on a backside of the memory array, and a first voltage drain to drain (VDD) rail on a frontside of the memory array, and a logic array including a second ground rail on a backside of the logic array, and a second VDD rail on the backside of the logic array. Thus, the memory array and the logic array use different power rails.

In one embodiments, which can be combined with the previous embodiment, the memory array further includes a first top transistor stacked over a first bottom transistor. The first top transistor includes a first top source/drain region, and a first contact connecting the first top source/drain region to the first VDD rail through a first top via. The first bottom transistor includes a first bottom source/drain region, and a second bottom source/drain region. Thus, the memory array can be a stacked transistor.

In one embodiments, which can be combined with one or more previous embodiments, the memory array further includes a first backside contact connecting the first bottom source/drain region to the first ground rail, and a second contact connecting the second bottom source/drain region to a bitline through a second top via. The memory array can include a top-bottom power.

In one embodiments, which can be combined with one or more previous embodiments, at least one of the first top transistor and the first bottom transistor is a field-effect transistor (FET). The memory can be a stacked FET, thus instead of relying solely on lateral scaling, which has its limits, the memory array includes increased transistor count within a given chip area compared to conventional non-tacked transistors.

In one embodiments, which can be combined with one or more previous embodiments, the memory array is a Static Random Access Memory (SRAM) device. The memory can be a stacked SRAM.

In one embodiments, which can be combined with one or more previous embodiments, the logic array further includes a second top transistor stacked over a second bottom transistor. The second top transistor includes a second top source/drain region, and a second top contact connecting the second top source/drain region to the second VDD rail through a deep via. The second bottom transistor includes a third bottom source/drain region. The logic array can be a stacked transistor, thus instead of relying solely on lateral scaling, which has its limits, the logic array includes increased transistor count within a given chip area compared to conventional non-tacked transistors.

In one embodiments, which can be combined with one or more previous embodiments, the second bottom transistor further incudes a second backside contact connecting the third bottom source/drain region to the second ground rail. The logic array can include backside power rails.

In one embodiments, which can be combined with one or more previous embodiments, at least one of the second top transistor and the second bottom transistor is a field-effect transistor (FET). The logic array can be a stacked FET, thus instead of relying solely on lateral scaling, which has its limits, the logic array includes increased transistor count within a given chip area compared to conventional non-tacked transistors.

According to an embodiment, a method for fabricating a semiconductor device includes forming a memory array including forming a first ground rail on a backside of the memory array, and forming a first voltage drain to drain (VDD) rail on a frontside of the memory array, and forming a logic array. Forming the logic array includes forming a second ground rail on a backside of the logic array, and forming a second VDD rail on a frontside of the logic array. Thus, the memory array and the logic array use different power rails.

In one embodiments, which can be combined with the previous embodiment, forming the memory array further includes forming a first top transistor, forming a first bottom transistor and stacking the first top transistor over the first bottom transistor. Forming the first top transistor can include forming a first top source/drain region, and connecting, by a first top contact, the first top source/drain region to the first VDD rail through a first top via. Forming the first bottom transistor includes forming a first bottom source/drain region, and forming a second bottom source/drain region. Thus, the memory array can be a stacked transistor and use two separate backside power rail and frontside power rail.

In one embodiments, which can be combined with one or more previous embodiments, forming the memory array further includes forming a first backside contact connecting the first bottom source/drain region to the first ground rail, and forming a second contact connecting the second bottom source/drain region to a bitline through a second top via. The memory array can include a top-bottom power.

In one embodiments, which can be combined with one or more previous embodiments, forming the logic array further includes forming a second top transistor. Forming a second bottom transistor and stacking the second top transistor over the second bottom transistor. Forming the second top transistor includes forming a second top source/drain region, and forming a second top contact connecting the second top source/drain region to the second VDD rail through a second top via. Forming the second bottom transistor includes a third bottom source/drain region. The logic array can be a stacked transistor, thus instead of relying solely on lateral scaling, which has its limits, the logic array includes increased transistor count within a given chip area compared to conventional non-tacked transistors.

In one embodiments, which can be combined with one or more previous embodiments, forming the second bottom transistor includes forming a second backside contact connecting the third bottom source/drain region to the second ground rail. The logic array can include backside power rails.

According to an embodiment, a semiconductor device includes a memory array including a first top source/drain region, and a first contact connecting the first top source/drain region to a memory voltage drain to drain (VDD) rail through a first top via. The memory VDD rail is located on a frontside of the memory array, and a logic array including a logic ground rail and a logic VDD rail. The logic ground rail and the logic VDD rail are located on a backside of the logic array. Thus, the memory array and the logic array can use difference power rails.

In one embodiments, which can be combined with the previous embodiment, the memory array further includes a memory ground rail on a backside of the memory array. In this way, the memory array can include separate backside and frontside power rails.

In one embodiments, which can be combined with one or more previous embodiments, the memory array further includes a first top transistor stacked over a first bottom transistor. The first bottom transistor includes a first bottom source/drain region, and a second bottom source/drain region. The memory array can be stacked transistor with separate backside and frontside power rails.

In one embodiments, which can be combined with one or more previous embodiments, the memory array further includes a first backside contact connecting the first bottom source/drain region to the memory ground rail, and a second contact connecting the second bottom source/drain region to a bitline through a second top via. The memory array can include a top to bottom power.

In one embodiments, which can be combined with one or more previous embodiments, at least one of the first top transistor and the first bottom transistor is a field-effect transistor (FET). The memory array can be a stacked FET, thus instead of relying solely on lateral scaling, which has its limits, the memory array includes increased transistor count within a given chip area compared to conventional non-tacked transistors.

In one embodiments, which can be combined with one or more previous embodiments, the memory array is a Static Random Access Memory (SRAM) device. The memory array can be a stacked SRAM device.

In one embodiments, which can be combined with one or more previous embodiments, the logic array includes a second top transistor stacked over a second bottom transistor. The second top transistor includes a second top source/drain region, and a second top contact connecting the second top source/drain region to the logic VDD rail through a deep top via. The second bottom transistor further includes a third bottom source/drain region. Thus, even the top transistor of the stacked FET of the logic array is connected to the backside power rail through a deep via.

In one embodiments, which can be combined with one or more previous embodiments, the second bottom transistor includes a second backside contact connecting the third bottom source/drain region to the second ground rail. In this way, the logic array can include backside power rails.

According to an embodiment, a method of fabricating a semiconductor includes forming a memory array including forming a first top source/drain region, and forming a first contact connecting the first top source/drain region to a memory voltage drain to drain (VDD) rail through a first top via. The memory VDD rail is located on a frontside of the memory array. Forming a logic array includes forming a logic ground rail, and forming a logic VDD rail. The logic ground rail and the logic VDD rail are located on a backside of the logic array. Thus, the memory array and the logic array use different power rails.

In one embodiments, which can be combined with the previous embodiment, the method includes forming a first top transistor, and forming a top bottom transistor and stacking the first top transistor over the first bottom transistor. Forming the first bottom transistor includes forming a first bottom source/drain region, and forming a second bottom source/drain region. The memory array can be a stacked transistor with separate backside and frontside power rails.

In one embodiments, which can be combined with one or more previous embodiments, forming the memory array includes forming a first backside contact connecting the first bottom source/drain region to the memory ground rail, and forming a second contact connecting the second bottom source/drain region to a bitline through a second top via. The memory array can include a top to bottom power.

In one embodiments, which can be combined with one or more previous embodiments, forming the logic array includes forming a second top transistor, forming a second bottom transistor and stacking the second top transistor over the second bottom transistor. Forming the second top transistor includes forming a second top source/drain region, and forming a second top contact connecting the second top source/drain region to the logic VDD rail through a deep via. Forming the second bottom transistor includes forming a third bottom source/drain region. Thus, the logic array includes backside power rails, which can be different from the memory array's power rails.

The concepts herein relate to stacked field-effect transistors (FETs), the adoption of which has represented a significant advancement in semiconductor technology, offering the potential for continued area scaling and performance enhancement. One aspect of this architecture is the utilization of backside power rails, which play a crucial role in realizing the benefits of block-level area scaling. By relocating power distribution to the backside of the chip, more surface area on the frontside becomes available for signal interconnects, allowing for denser integration of functional blocks and improved overall chip efficiency.

A consideration in optimizing stacked FET performance is the implementation of direct backside contact, which is instrumental in reducing source/drain-side contact resistance. However, while this approach offers substantial benefits for the bottom FET, challenges arise when applying it to the top FET. Due to the need to connect the top FET's source/drain contact to the backside, vias that are deep enough to reach from the top FET source/drain region to the backside are salient, introducing a tradeoff between area scaling and resistance. Addressing such a tradeoff requires design considerations and optimization strategies to balance performance requirements with layout constraints.

Furthermore, requirements of different circuit components must be taken into account when designing stacked FET architectures. While logic circuits typically necessitate both voltage drain to drain (VDD) and ground (GND) connections on the backside for optimal performance, the same may not hold true for static random access memory (SRAM) arrays. SRAM arrays often have well-defined and relatively relaxed signal connections, such as wordlines (WL) and bitlines (BL), which may not require VDD and GND connections on the backside. This distinction highlights the importance of tailoring design approaches to the specific needs of different circuit elements within a stacked FET architecture. Beyond addressing backside power distribution and contact resistance challenges, optimizing stacked FET designs involves tackling a range of additional considerations. These include managing interconnect complexity to minimize parasitic effects, integrating heterogeneous materials and devices for enhanced performance, and developing advanced packaging and 3D integration techniques to improve connectivity and reduce signal delays.

The disclosed semiconductor device includes logic array that utilizes both VDD and GND rails on the backside of the logic array and a memory array that utilizes one power rail on the backside and one power rail on the frontside of the memory array. Such configurations facilitate efficient power distribution and ground connections by incorporating VDD and GND rails on the backside of the logic array to minimize signal interference, while incorporating VDD and GND rails on the backside and frontside of the memory array to meet the operational considerations of the densely packed memory cells and allow for efficient grounding and noise reduction within the memory array, thereby enhancing stability and reliability.

Accordingly, the teachings herein provide methods and systems of semiconductor device formation with distributed power rails. The techniques described herein may be implemented in a number of ways. Example implementations are provided below with reference to the following figures.

Example Semiconductor Device with Distributed Power Rails Structure

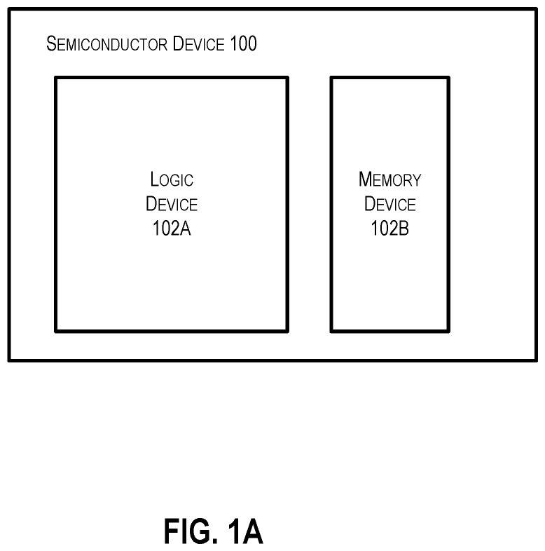

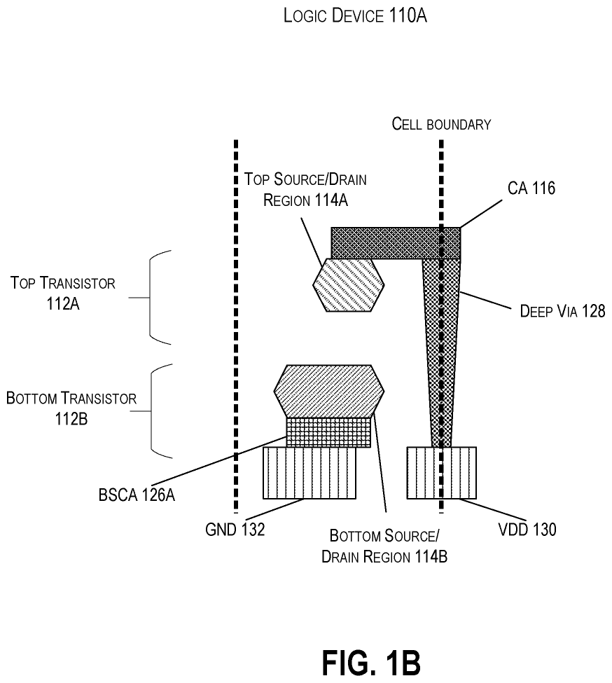

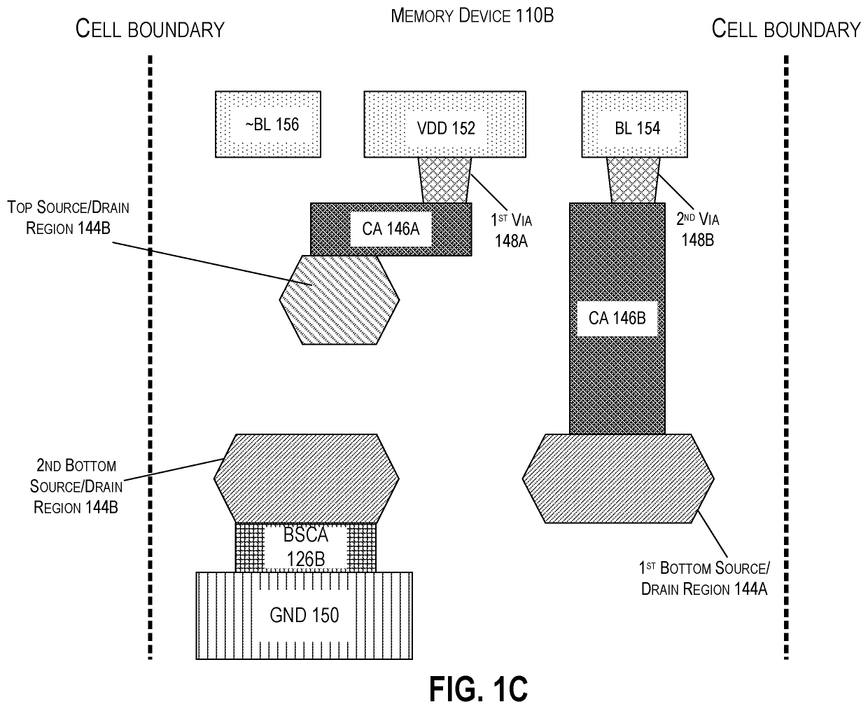

FIG. 1A illustrates an exemplary semiconductor device, consistent with an illustrative embodiment. The semiconductor device 100 includes a logic array 102A and a memory array 102B. The memory array 102B can be a static random-access memory (SRAM). It should be noted that, while an SRAM is depicted in figures, the memory array 102B can include any suitable memory array. Reference now is made to FIGS. 1B-1C, which are simplified cross-sections view of a semiconductor device, consistent with an illustrative embodiment. In various embodiments, the semiconductor device includes a logic array 110A and a memory array 110B. While, for the sake of simplicity, the logic array 110A and the memory array 110B are depicted separately, it should be noted that the logic array 110A and the memory array 110B can be integrated on a same semiconductor device adjacent to each other. Moreover, and to avoid crowded drawings, the logic array 110A is shown in FIG. 1A, and the memory array 110B is shown in FIG. 1C.

Referring to FIG. 1B now, the logic array 110A can be a stacked field effect transistor (FET). The logic array 110A is a stacked FET that leverages the vertical dimension of the semiconductor device to increase the number of active devices within a given area. This way, instead of relying solely on lateral scaling, where semiconductor devices are shrunk in size on the semiconductor substrate, stacking FETs vertically can enable the incorporation of multiple layers of semiconductor devices. This arrangement enables more complex circuitry and advanced functionality.

In some embodiments, the stacked FET structure of the logic array 110A can enable higher integration densities by utilizing the vertical dimension of the semiconductor device. In such embodiments, instead of relying solely on lateral scaling, which has its limits, stacking FETs on the semiconductor device allows for increased transistor count within a given chip area. This increased transistor count enables the integration of more complex circuits, larger memory arrays, and other functional blocks, enhancing the capabilities of the semiconductor device.

The logic array 110A can include a top transistor 112A and a bottom transistor 112B. The logic array 110A can include a top source/drain region 114A, a bottom source/drain region 114B, a source/drain contact, CA 116, a first backside contact, BSCA 126A, a deep via 128, a logic voltage drain to drain (VDD) rail, VDD 130, and a ground rail, GND 132. The VDD 103 and the GND 132 are located on the backside of the logic array 110A.

Generally, the top source/drain region 114A and the bottom source/drain region 114B are components that play salient roles in the logic array 110A operation. In some embodiments, the top source/drain region 114A and the bottom source/drain region 114B are regions within the semiconductor material, e.g., the logic array 110A, where the current flows in and out of the logic array 110A. The source region is the region through which the majority of charge carriers (e.g., electrons or holes) enter the channel of the logic array 110A and is responsible for providing the current that flows through the logic array 110A. The source region is typically doped to have an excess of charge carriers, creating a region with high carrier concentration. This abundance of carriers allows for the efficient injection of electrons or holes into the channel when a voltage is applied.

On the other hand, the drain region is where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In some embodiments, the top source/drain region 114A is connected to a backside of the logic array 110A via the CA 116 and the deep via 128. In an embodiment, the bottom source/drain region 114B is connected to the backside of the logic array 110A via the BSCA 126A.

The CA 116 ensures efficient electrical routing and connectivity within the logic array 110A. The fabrication of the CA 116 can involve lithography and etching processes to define the contact area. The CA 116 can be made using conductive materials such as a silicide liner, e.g., Ni, Ti, NiPt, an adhesion metal layer, e.g., TiN and conductive metal fill material, e.g., tungsten (W), Co, or Ru.

The BSCA 126A is a region on the backside of the logic array 110A where electrical connections are made. By establishing the electrical contacts, the BSCA 126A ensures the proper functioning of the logic array 110A and facilitates electrical signal transmission.

The BSCA 126A can serve as a thermal interface between the logic array 110A and a heat sink or other cooling mechanisms. By establishing direct contact with the substrate, the BSCA 126A can conduct the heat away from the logic array 110A, and contribute to improved thermal dissipation. In some embodiments, the BSCA 126A can help mitigate parasitic effects, such as substrate coupling or substrate noise, from the logic array 110A. In further embodiments, the BSCA 126A can allow for increased integration density in the logic array 110A. In an embodiment, the BSCA 126A connects, i.e., wires, the bottom source/drain region 114B to the GND 132.

Reference is now made to FIG. 1C, which illustrates the memory array 110B of a semiconductor device, according to some embodiments. The memory array 110B includes a top source/drain region 144A, a first bottom source/drain region 144B, a second bottom source/drain region 144C, a first contact, CA 146A, a second contact, CA 146B, a second backside contact, BSCA 126B, a first via 148A, a second via 148B, a GND 150, a VDD 152, and a bitline, BL 154.

The top source/drain region 144A, the first bottom source/drain region 144B, and the second bottom source/drain region 144C are regions within the memory array 110B where the current flows in and out of the memory array 110B. The source region is the region through which the majority of charge carriers (e.g., electrons or holes) enter the channel of the memory array 110B and is responsible for providing the current that flows through the memory array 110B. The source region can be doped to have an excess of charge carriers, creating a region with high carrier concentration. This abundance of carriers allows for the efficient injection of electrons or holes into the channel when a voltage is applied. On the other hand, the drain region is where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The CA 146A electrically connects the top source/drain region 144A to the VDD 152 (GND 150) via the first via 148A. CA 146A ensures efficient electrical routing and connectivity within the memory array 110B. The fabrication of the CA 146A can involve lithography and etching processes to define the contact area. The CA 146A can be made using conductive materials such as a silicide liner, e.g., Ni, Ti, NiPt, an adhesion metal layer, e.g., TiN and conductive metal fill material, e.g., tungsten (W), Co, or Ru.

The CA 146B electrically connects the first bottom source/drain region 144B to the BL 154 via the second via 148B. CA 146B ensures efficient electrical routing and connectivity within the memory array 110B. The fabrication of the CA 146B can involve lithography and etching processes to define the contact area. The CA 146B can be made using conductive materials such as a silicide liner, e.g., Ni, Ti, NiPt, an adhesion metal layer, e.g., TiN and conductive metal fill material, e.g., tungsten (W), Co, or Ru.

The BSCA 126B is a region on the backside of the memory array 110B where electrical connections are made. By establishing the electrical contacts, the BSCA 126B ensures the proper functioning of the memory array 110B and facilitates electrical signal transmission. The BSCA 126B can serve as a thermal interface between the memory array 110B and a heat sink or other cooling mechanisms. By establishing direct contact with the substrate, the BSCA 126B can conduct the heat away from the memory array 110B, and contribute to improved thermal dissipation. In some embodiments, the BSCA 126B can help mitigate parasitic effects, such as substrate coupling or substrate noise, from the memory array 110B. In further embodiments, the BSCA 126B can allow for increased integration density in the memory array 110B. In an embodiment, the BSCA 126B connects, i.e., wires, the second bottom source/drain region 144C to the VDD 152 (GND 150).

The GND 150 can be the reference point for all voltages within the memory array 110B. It's the “zero” voltage level against which all other voltages are measured. As a non-limiting example, in the context of the SRAM cell, the GND 150 serves as the low voltage supply line and can ensure stable operation of the SRAM cell, as it completes the electrical circuit, allowing current to flow through the device.

The VDD 152, on the other hand, is the positive power supply voltage for the memory array 110B, which provides the power for the memory array 110B to operate. The VDD 152 can establish the high voltage level in the flip-flop circuitry of the SRAM cell, enabling it to store a ‘l’ bit. The VDD 152 can contrast with the GND 150, ensuring that the SRAM can operate by providing the two essential voltage levels for the digital logic.

BL 154 can be used for reading and writing data. An SRAM cell is typically connected to two bitline: a BL and a complementary bitline (labeled “˜BL 154”. The bitlines can be used to access the SRAM cell during read and write operations. During a read, the state of the SRAM cell (either high or low voltage) is detected by sensing the differential voltage between the bitline and its complementary line. During a write operation, the bitlines are driven to the desired state to change the state of the SRAM cell, effectively updating its stored value.

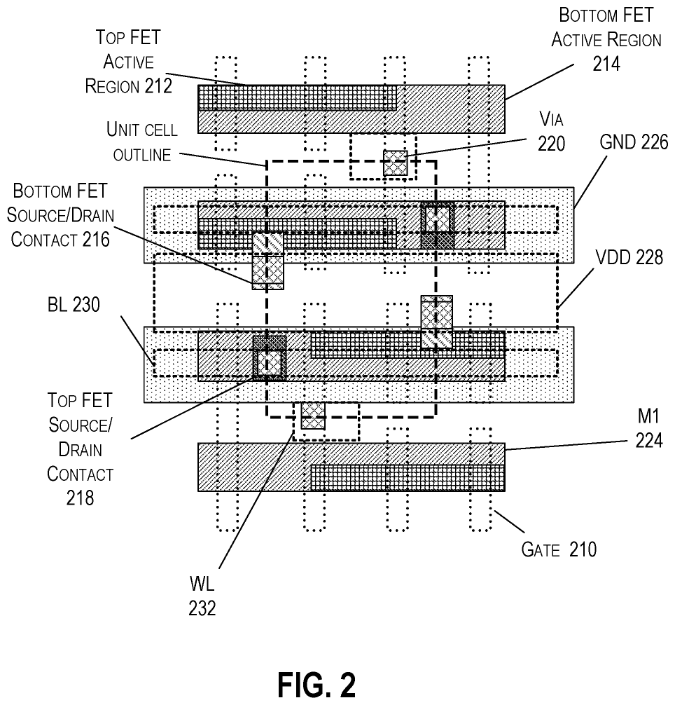

FIG. 2 illustrates a top-down view of an exemplary SRAM cell layout with top to bottom power, in accordance with some embodiments. In some embodiment, the SRAM cell can include a plurality of gates 210, a plurality of top FET active regions 212 stacked over a plurality of bottom FET active regions 214, a plurality of bottom source/drain contacts 216, plurality of top source/drain contacts 218, a plurality of vias 220, a plurality of backside metal lines 222, backside GND 226, frontside VDD 228, BL 230, and wordline, WL 232.

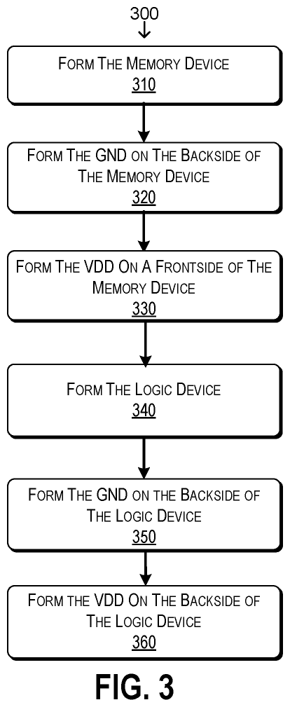

FIG. 3 illustrates a block diagram of a method 300 for forming the semiconductor device, in accordance with some embodiments. As shown by block 310, a memory array is formed.

As shown in block 320, to form the memory array, a first ground rail on a backside of the memory array is formed.

As shown in block 330, as part of forming the memory array, a first voltage drain to drain (VDD) rail on a frontside of the memory array is formed.

As shown in block 340, a logic array is formed.

As shown in block 350, to form the logic array, a second ground rail on a backside of the logic array is formed.

As shown in block 360, as part of forming the logic array, a second VDD rail on a frontside of the logic array is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a memory array comprising:
a first ground rail on a backside of the memory array; and
a first voltage drain to drain (VDD) rail on a frontside of the memory array; and
a logic array comprising:
a second ground rail on a backside of the logic array; and
a second VDD rail on the backside of the logic array.

2. The semiconductor device of claim 1, wherein:
the memory array further comprises a first top transistor stacked over a first bottom transistor;
the first top transistor comprises:
a first top source/drain region; and
a first contact connecting the first top source/drain region to the first VDD rail through a first top via; and
the first bottom transistor comprises:
a first bottom source/drain region; and
a second bottom source/drain region.

3. The semiconductor device of claim 2, wherein the memory array further comprises:
a first backside contact connecting the first bottom source/drain region to the first ground rail; and
a second contact connecting the second bottom source/drain region to a bitline through a second top via.

4. The semiconductor device of claim 2, wherein at least one of the first top transistor or the first bottom transistor is a field-effect transistor (FET).

5. The semiconductor device of claim 2, wherein the memory array is a Static Random Access Memory (SRAM) device.

6. The semiconductor device of claim 1, wherein:
the logic array further comprises a second top transistor stacked over a second bottom transistor;
the second top transistor comprises:
a second top source/drain region;
a second top contact connecting the second top source/drain region to the second VDD rail through a deep via; and
the second bottom transistor comprises a third bottom source/drain region.

7. The semiconductor device of claim 6, wherein the second bottom transistor further comprises a second backside contact connecting the third bottom source/drain region to the second ground rail.

8. The semiconductor device of claim 6, wherein at least one of the second top transistor or the second bottom transistor is a field-effect transistor (FET).

9. A method for fabricating a semiconductor device, the method comprising:
forming a memory array, comprising:
forming a first ground rail on a backside of the memory array; and
forming a first voltage drain to drain (VDD) rail on a frontside of the memory array; and
forming a logic array, comprising:
forming a second ground rail on a backside of the logic array; and
forming a second VDD rail on a frontside of the logic array.

10. The method of claim 9, wherein forming the memory array further comprises:
forming a first top transistor; and
forming a first bottom transistor;
stacking the first top transistor over the first bottom transistor,
wherein forming the first top transistor comprises:
forming a first top source/drain region; and
connecting, by a first top contact, the first top source/drain region to the first VDD rail through a first top via; and
wherein forming the first bottom transistor comprises:
forming a first bottom source/drain region; and
forming a second bottom source/drain region.

11. The method of claim 10, wherein forming the memory array further comprises:
forming a first backside contact connecting the first bottom source/drain region to the first ground rail; and
forming a second contact connecting the second bottom source/drain region to a bitline through a second top via.

12. The method of claim 9, wherein forming the logic array further comprises:
forming a second top transistor; and
forming a second bottom transistor and stacking the second top transistor over the second bottom transistor,
wherein forming the second top transistor comprises:
forming a second top source/drain region; and
forming a second top contact connecting the second top source/drain region to the second VDD rail through a second top via; and
wherein the second bottom transistor comprises a third bottom source/drain region.

13. The method of claim 12, wherein forming the second bottom transistor further comprises forming a second backside contact connecting the third bottom source/drain region to the second ground rail.

14. A semiconductor device, comprising:
a memory array comprising a first top source/drain region, and a first contact connecting the first top source/drain region to a memory voltage drain to drain (VDD) rail through a first top via, wherein the memory VDD rail is located on a frontside of the memory array; and
a logic array comprising a logic ground rail and a logic VDD rail, wherein the logic ground rail and the logic VDD rail are located on a backside of the logic array.

15. The semiconductor device of claim 14, wherein the memory array further comprises a memory ground rail on a backside of the memory array.

16. The semiconductor device of claim 14, wherein:
the memory array further comprises a first top transistor stacked over a first bottom transistor; and
the first bottom transistor comprises:
a first bottom source/drain region; and
a second bottom source/drain region.

17. The semiconductor device of claim 14, wherein the memory array further comprises:
a first backside contact connecting a first bottom source/drain region to a memory ground rail; and
a second contact connecting a second bottom source/drain region to a bitline through a second top via.

18. The semiconductor device of claim 16, wherein at least one of the first top transistor and the first bottom transistor is a field-effect transistor (FET).

19. The semiconductor device of claim 14, wherein the memory array is a Static Random Access Memory (SRAM) device.

20. The semiconductor device of claim 14, wherein:
the logic array further comprises a second top transistor stacked over a second bottom transistor;
the second top transistor comprises:
a second top source/drain region; and
a second top contact connecting the second top source/drain region to the logic VDD rail through a deep top via; and
the second bottom transistor comprises a third bottom source/drain region.

21. The semiconductor device of claim 20, wherein the second bottom transistor further comprises a second backside contact connecting the third bottom source/drain region to the logic ground rail.

22. A method of fabricating a semiconductor, the method comprising:
forming a memory array comprising:
forming a first top source/drain region; and
forming a first contact connecting the first top source/drain region to a memory voltage drain to drain (VDD) rail through a first top via, wherein the memory VDD rail is located on a frontside of the memory array; and
forming a logic array comprising:
forming a logic ground rail; and
forming a logic VDD rail, wherein the logic ground rail and the logic VDD rail are located on a backside of the logic array.

23. The method of claim 22, further comprising:
forming a first top transistor; and
forming a top bottom transistor; and
stacking the first top transistor over a first bottom transistor,
wherein forming the first bottom transistor comprises:
forming a first bottom source/drain region; and
forming a second bottom source/drain region.

24. The method of claim 22, wherein forming the memory array further comprises:
forming a first backside contact connecting a first bottom source/drain region to a memory ground rail; and
forming a second contact connecting a second bottom source/drain region to a bitline through a second top via.

25. The method of claim 22, wherein forming the logic array further comprises:
forming a second top transistor; and
forming a second bottom transistor and stacking the second top transistor over the second bottom transistor, wherein:
forming the second top transistor comprises:
forming a second top source/drain region; and
forming a second top contact connecting the second top source/drain region to the logic VDD rail through a deep via; and
forming the second bottom transistor comprises forming a third bottom source/drain region.
